(19) United States
(12) Patent Application Publication
(10) Pub. No.: US 2023/0329038 A1
(43) Pub. Date: Oct. 12, 2023

(54) DISPLAY DEVICE AND METHOD FOR MANUFACTURING SAME

(71) Applicant: SHARP KABUSHIKI KAISHA, Sakai City, Osaka (JP)

(72) Inventors: TAKAO SAITOH, Sakai City, Osaka (JP); YOHSUKE KANZAKI, Sakai City, Osaka (JP); MASAKI YAMANAKA, Sakai City, Osaka (JP); MASAHIKO MIWA, Sakai City, Osaka (JP); YI SUN, Sakai City, Osaka (JP)

(21) Appl. No.: 18/025,094

(22) PCT Filed: Sep. 8, 2020
(86) PCT No.: PCT/JP2020/033853

§ 371 Date: Mar. 7, 2023

(51) Int. Cl. H10K 59/121; H10K 59/131; H10K 59/12

(52) U.S. Cl. CPC H10K 59/1216; H10K 59/1213; H10K 59/131; H10K 59/1201

(57) ABSTRACT

A capacitor (9ha) includes a gate electrode (14a), a first interlayer insulating film (15), a capacitance electrode (16c), and a capacitance wiring line (18ha). The capacitance wiring line (18ha) is electrically connected to the capacitance electrode (16c). A capacitance of the capacitor (9ha) is formed between the gate electrode (14a) and the capacitance electrode (16c) and the capacitance wiring line (18ha) arranged facing each other across the first interlayer insulating film (15). A line width (W₁₈ₕ) of the capacitance wiring line (18ha) is equal to or greater than a line width (W_{16c}) of the capacitance electrode (16c) and equal to or less than a line width (W₁₄ₐ) of the gate electrode (14a).

### TECHNICAL FIELD

The present invention relates to a display device and a method for manufacturing the same.

### BACKGROUND ART

In recent years, self-luminous organic electroluminescence (hereinafter also referred to as EL) display devices using organic EL elements have attracted attention as display devices that can replace liquid crystal display devices. Here, for example, in an organic EL display device employing an active matrix driving method, a plurality of thin film transistors (hereinafter also referred to as “TFTs”) including a drive TFT, and a capacitor (capacitance element) electrically connected to the drive TFT, are provided for each of a subpixel being the smallest unit of an image.

For example, PTL 1 discloses a configuration in which two or more upper holding capacitance electrodes are provided being arranged facing a holding capacitance wiring line, a contact hole is formed in an interlayer insulating film on each of the upper holding capacitance electrodes, and a pixel electrode on the interlayer insulating film is conductively connected to a corresponding one of the holding capacitance electrodes, via the contact hole.

### CITATION LIST

### Patent Literature

PTL 1: JP 2008-287290 A

### SUMMARY OF INVENTION

### Technical Problem

There has been proposed an organic EL display device having a structure in which a capacitor of each of subpixels includes, for example, a lower electrode and an upper electrode provided so as to face each other, and an inorganic insulating film provided between the lower electrode and the upper electrode, and in which in each subpixel, a gate electrode of a drive TFT is provided integrally with the lower electrode of the capacitor in an island shape.

Here, in the organic EL display device having the above-described structure, an etching shift may occur when a metal film is formed and then patterned in order to form the upper electrode. For example, when an etching shift amount is large, a line width of the upper electrode is smaller than a line width of the lower electrode. In a capacitor in which such a problem occurs, capacitance decreases as an area of a portion where the upper electrode and the lower electrode overlap with each other in a plan view decreases (an area forming the capacitance of the capacitor). Thus, when the capacitance of the capacitor of each subpixel changes due to a variation in the etching shift amount, there is a concern that display unevenness (irregularity) may occur when an image is displayed.

The present invention has been made in view of the above, and an object of the present invention is to suppress a capacitance change in the capacitor of each subpixel.

### Solution to Problem

In order to achieve the above object, a display device according to the present invention includes a base substrate, a thin film transistor layer provided on the base substrate, layered with a semiconductor layer, a gate insulating film, a first metal layer, a first interlayer insulating film, a second metal layer, a second interlayer insulating film, and a third metal layer in order, and including a thin film transistor and a capacitor arranged for each of subpixels, and an organic EL element layer (light-emitting element layer) provided on the thin film transistor layer and including a light-emitting element arranged for each of the subpixels, the thin film transistor including the semiconductor layer, the gate insulating film covering the semiconductor layer, and a gate electrode provided as the first metal layer on the gate insulating film and arranged in an island shape overlapping with a part of the semiconductor layer in a plan view, in which the capacitor includes the gate electrode, the first interlayer insulating film provided on the gate electrode, a capacitance electrode provided as the second metal layer on the first interlayer insulating film and overlapping with the gate electrode in a plan view, and a capacitance wiring line provided as the third metal layer on the capacitance electrode and overlapping with the capacitance electrode and the gate electrode in a plan view, the capacitance wiring line is electrically connected to the capacitance electrode, a capacitance of the capacitor is formed between the gate electrode and the capacitance electrode and the capacitance wiring line facing each other across the first interlayer insulating film, and a line width of the capacitance wiring line is equal to or greater than a line width of the capacitance electrode and equal to or less than a line width of the gate electrode.

### Advantageous Effects of Invention

According to the present invention, it is possible to suppress a capacitance change of the capacitor of each subpixel.

### BRIEF DESCRIPTION OF DRAWINGS

FIG. 1 is a plan view illustrating a schematic configuration of an organic EL display device according to a first embodiment of the present invention.

FIG. 2 is a plan view of a display region of the organic EL display device according to the first embodiment of the present invention.

FIG. 3 is a cross-sectional view of the display region of the organic EL display device according to the first embodiment of the present invention.

FIG. 4 is an equivalent circuit diagram of a TFT layer constituting the organic EL display device according to the first embodiment of the present invention.

FIG. 5 is a plan view of a TFT layer included in the organic EL display device according to the first embodiment of the present invention.

FIG. 6 is a cross-sectional view of a TFT layer included in the organic EL display device, taken along line VI-VI in FIG. 5.

FIG. 7 is a plan view schematically illustrating a capacitor included in the TFT layer of the organic EL display device according to the first embodiment of the present invention.

FIG. 8 is a cross-sectional view schematically illustrating the capacitor included in the TFT layer of the organic EL display device, taken along line A-A in FIG. 7, and is a view illustrating a state where a line width of a capacitance electrode included in the capacitor is reduced.

FIG. 9 is a cross-sectional view schematically illustrating the capacitor included in the TFT layer of the organic EL display device, taken along line A-A in FIG. 7, and is a view illustrating a state where the line width of the capacitance electrode included in the capacitor is not reduced.

FIG. 10 is a cross-sectional view illustrating an organic EL layer included in the organic EL display device according to the first embodiment of the present invention.

FIG. 11 is a plan view schematically illustrating a capacitor included in a TFT layer of an organic EL display device according to a second embodiment of the present invention, and corresponds to FIG. 7.

FIG. 12 is a cross-sectional view schematically illustrating the capacitor included in the TFT layer of the organic EL display device, taken along line B-B in FIG. 11, is a view illustrating a state where a line width of a capacitance electrode included in the capacitor is reduced, and corresponds to FIG. 8.

FIG. 13 is a cross-sectional view schematically illustrating the capacitor included in the TFT layer of the organic EL display device, taken along line B-B in FIG. 11, is a view illustrating a state where the line width of the capacitance electrode included in the capacitor is not reduced, and corresponds to FIG. 9.

### DESCRIPTION OF EMBODIMENTS

Embodiments of the present invention will be described below in detail with reference to the drawings. Note that the present invention is not limited to each embodiment to be described below.

### First Embodiment

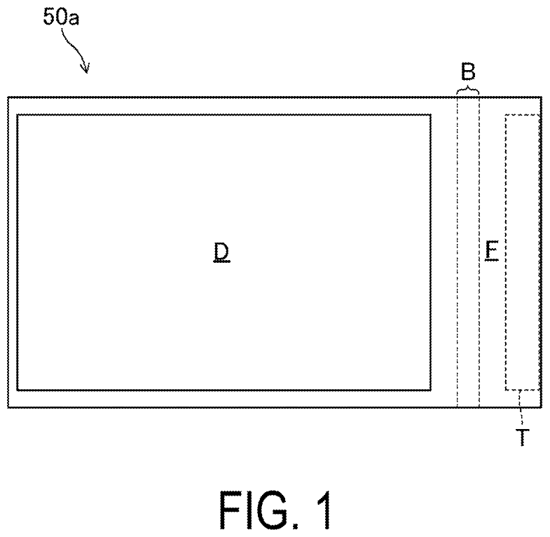

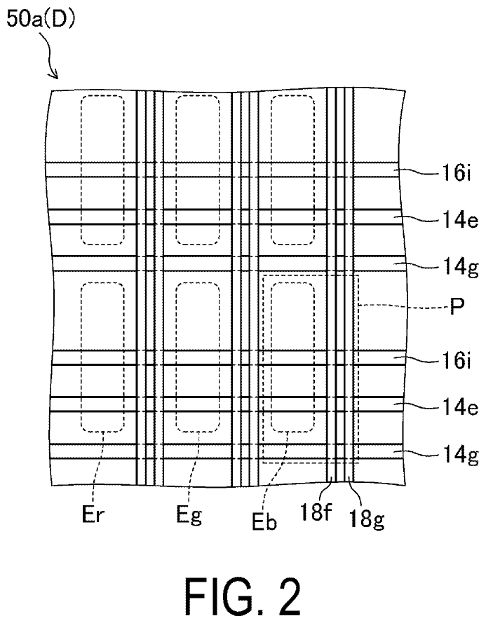

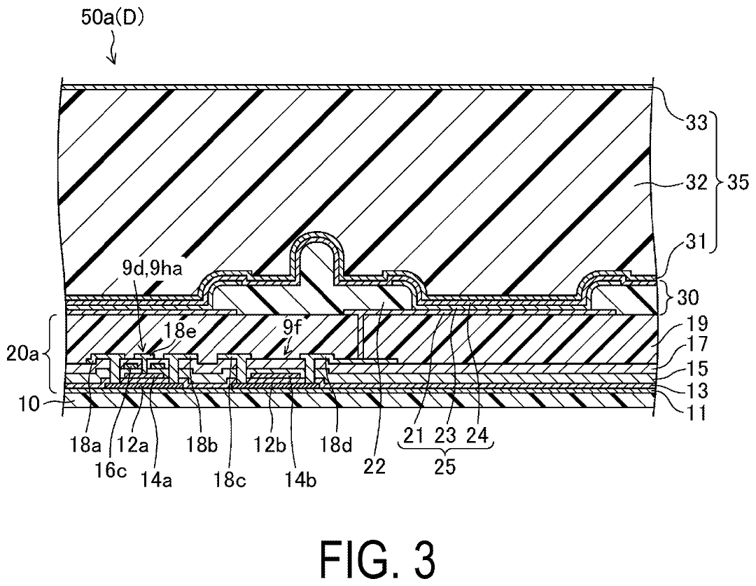

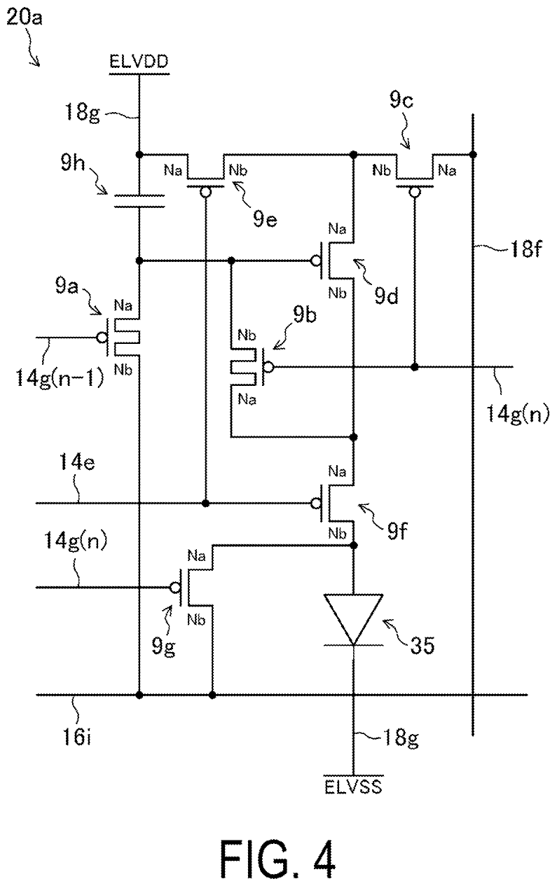

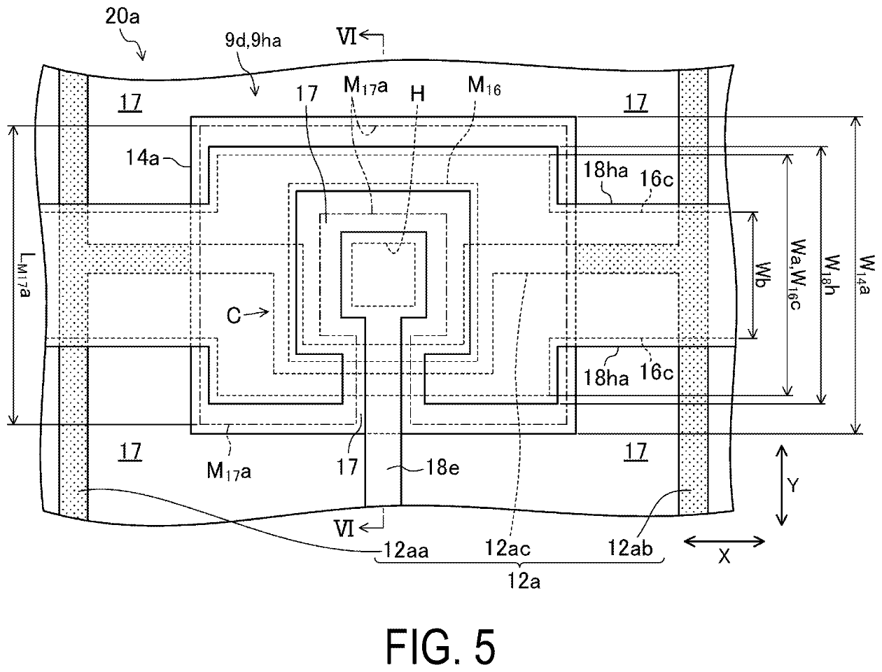

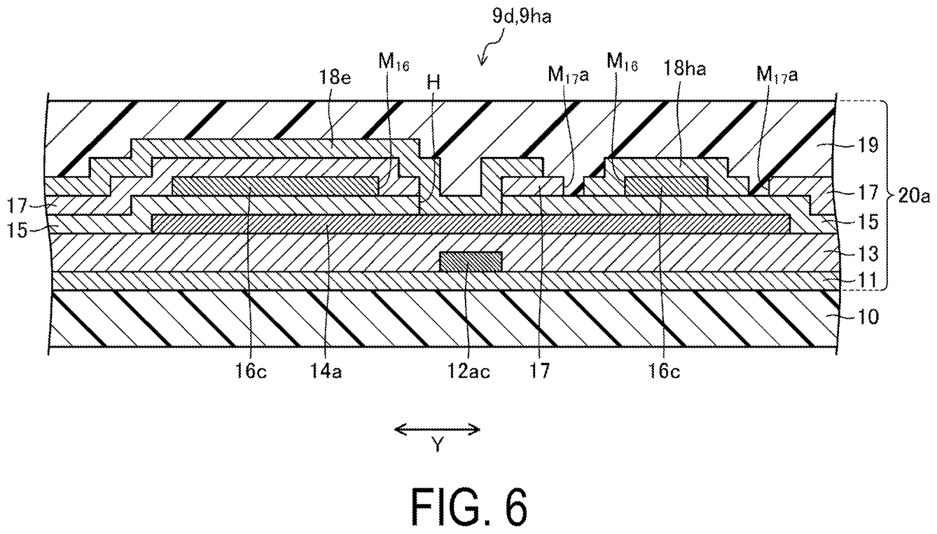

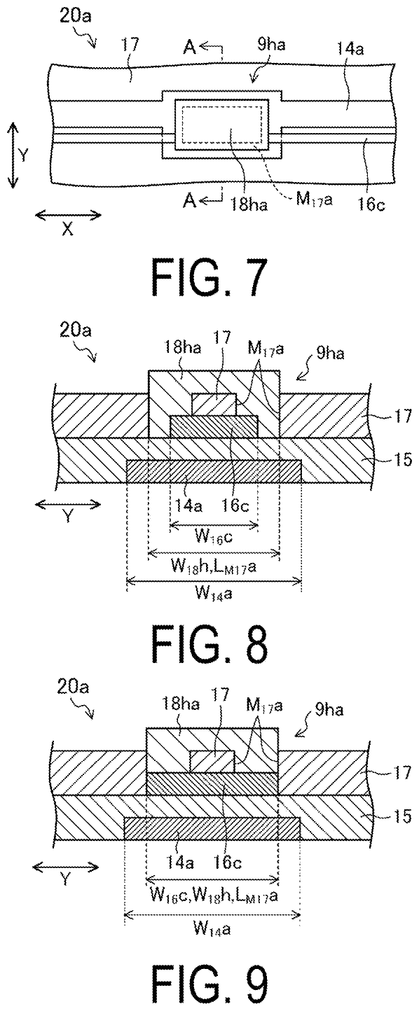

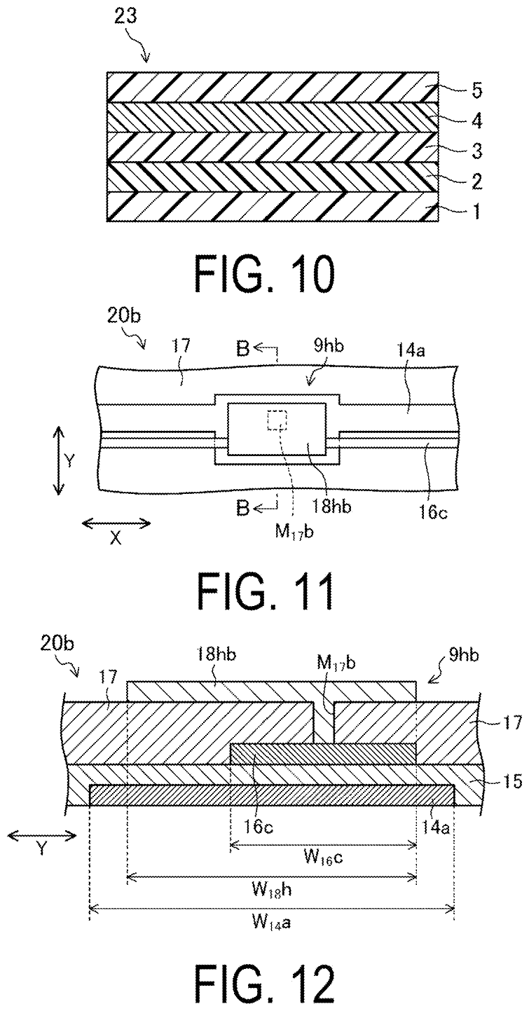

FIGS. 1 to 10 illustrate a first embodiment of a display device and a method for manufacturing the same according to the present invention. Note that, in each of the following embodiments, an organic EL display device including an organic EL element will be exemplified as a display device including a light-emitting element. Here, FIG. 1 is a plan view illustrating a schematic configuration of an organic EL display device 50a according to the present embodiment. Further, FIG. 2 is a plan view of a display region D of the organic EL display device 50a. Further, FIG. 3 is a cross-sectional view of the display region D of the organic EL display device 50a. Further, FIG. 4 is an equivalent circuit diagram of a thin film transistor layer (TFT layer) 20a included in the organic EL display device 50a. Further, FIG. 5 is a plan view of the TFT layer 20a included in the organic EL display device 50a. Further, FIG. 6 is a cross-sectional view of the TFT layer 20a taken along line VI-VI in FIG. 5. Further, FIG. 7 is a plan view schematically illustrating a capacitor 9ha included in the TFT layer 20a of the organic EL display device 50a. Further, FIG. 7 is a cross-sectional view schematically illustrating the capacitor 9ha, taken along line A-A in FIG. 7, and is a view illustrating a state where a line width of a capacitance electrode 16c included in the capacitor 9ha is reduced. Further, FIG. 9 is a cross-sectional view schematically illustrating the capacitor 9ha, taken along line A-A in FIG. 7, and is a view illustrating a state where the line width of the capacitance electrode 16c included in the capacitor 9ha is not reduced. Further, FIG. 10 is a cross-sectional view illustrating an organic EL layer 23 included in the organic EL display device 50a.

As illustrated in FIG. 1, the organic EL display device 50a includes, for example, the display region D that is provided in a rectangular shape and displays an image, and the frame region F provided in a frame-like shape around the display region D. Note that in the present embodiment, the display region D having the rectangular shape is exemplified, but the rectangular shape includes a substantial rectangular shape such as a shape whose sides are arc-shaped, a shape whose corners are arc-shaped, and a shape in which a part of a side has a notch.

A terminal portion T is provided in a central right end portion of the frame region F in FIG. 1. Further, as illustrated in FIG. 1, in the frame region F, a bendable bending portion B that can bend 1800 (in a U-shape) with the vertical direction in the drawing as a bending axis is provided between the display region D and the terminal portion T so as to extend in one direction (the vertical direction in the drawing).

As illustrated in FIG. 2, a plurality of subpixels P are arrayed in a matrix shape in the display region D. In addition, in the display region D, for example, a subpixel P including a red light-emitting region Er configured to display a red color, a subpixel P including a green light-emitting region Eg configured to display a green color, and a subpixel P including a blue light-emitting region Eb configured to display a blue color are provided adjacent to one another, as illustrated in FIG. 2. Note that one pixel is configured by, for example, the three adjacent subpixels P including the red light-emitting region Er, the green light-emitting region Eg, and the blue light-emitting region Eb in the display region D.

As illustrated in FIG. 3, the organic EL display device 50a includes a resin substrate layer 10 provided as a base substrate, the TFT layer 20a provided on the resin substrate layer 10, an organic EL element layer 30 provided as a light-emitting element layer on the TFT layer 20a, and a sealing film 35 provided on the organic EL element layer 30.

The resin substrate layer 10 is formed, for example, of a polyimide resin or the like.

As illustrated in FIG. 3 and FIG. 6, the TFT layer 20a includes a base coat film 11, semiconductor layers 12a (12ac) and 12b, a gate insulating film 13, a first metal layer (for example, gate electrodes 14a and 14b, a gate line 14g, and the like), a first interlayer insulating film 15, a second metal layer (for example, the capacitance electrode 16c, an initialization power source line 16i, and the like), a second interlayer insulating film 17, a third metal layer (for example, terminal electrodes 18a to 18d, a connection wiring line 18e, a source line 18f, a power source line 18g, and the like), and a flattening film 19 provided in order on the resin substrate layer 10.

Note that, each of the base coat film 11, the gate insulating film 13, the first interlayer insulating film 15, and the second interlayer insulating film 17 is composed of, for example, a single-layer film or a layered film of an inorganic insulating film of silicon nitride (SiNx (x is a positive number)), silicon oxide (SiO₂), silicon oxynitride, or the like. The first interlayer insulating film 15 is preferably composed of a single-layer film of SiNx (having a film thickness of about 100 nm). The second interlayer insulating film 17 is preferably composed of a layered film of SiNx/SiO₂ (having a film thickness of about 190 nm/270 nm). The semiconductor layers 12a and 12b are composed of, for example, a low-temperature polysilicon film, an In—Ga—Zn—O-based oxide semiconductor film, or the like. Each of the first metal layer, the second metal layer, and the third metal layer is formed of, for example, a metal single layer film of a metal such as molybdenum (Mo), titanium (Ti), aluminum (Al), copper (Cu), or tungsten (W), or a metal layered film such as Mo (upper layer)/Al (intermediate layer)/Mo (lower layer), Ti/Al/Ti, Al (upper layer)/Ti (lower layer), Cu/Mo, or Cu/Ti. The first metal layer and the second metal layer are preferably formed of the same material, and are more preferably formed of Mo. The third metal layer is preferably formed of a metal layered film such as Ti/Al/Ti.

As illustrated in FIG. 3 and FIG. 4, the TFT layer 20a includes a first initialization TFT 9a, a threshold voltage compensation TFT 9b, a write control TFT 9c, a drive TFT 9d, a power source supply TFT 9e, a light emission control TFT 9f, a second initialization TFT 9g, and the capacitor 9ha provided as a pixel circuit for each subpixel P on the base coat film 11, and the flattening film 19 provided on each of the TFTs 9a to 9g and the capacitor 9ha. Here, in the TFT layer 20a, a plurality of the pixel circuits are arrayed in a matrix shape corresponding to the plurality of subpixels P. In the TFT layer 20a, as illustrated in FIG. 2, a plurality of the gate lines 14g (first metal layer) are provided so as to extend parallel to each other in a horizontal direction in the drawing. In the TFT layer 20a, as illustrated in FIG. 2, a plurality of light emission control lines 14e (first metal layer) are provided so as to extend parallel to each other in the horizontal direction in the drawing. Note that, as illustrated in FIG. 2, each of the light emission control lines 14e is provided adjacent to a corresponding one of the gate lines 14g. As illustrated in FIG. 2, in the TFT layer 20a, a plurality of the initialization power source lines 16i (second metal layer) are provided so as to extend parallel to each other in the horizontal direction in the drawing. As illustrated in FIG. 2, in the TFT layer 20a, a plurality of the source lines 18f (third metal layer) are provided so as to extend parallel to each other in the vertical direction in the drawing. As illustrated in FIG. 2, in the TFT layer 20a, a plurality of the power source lines 18g (third metal layer) are provided so as to extend parallel to each other in the vertical direction in the drawing. Note that, as illustrated in FIG. 2, each of the power source lines 18g is provided so as to be adjacent to a corresponding one of the source lines 18f.

Here, the first initialization TFT 9a, the threshold voltage compensation TFT 9b, the write control TFT 9c, the drive TFT 9d, the power source supply TFT 9e, the light emission control TFT 9f, and the second initialization TFT 9g each include a first terminal electrode (see reference symbol Na in FIG. 4) and a second terminal electrode (see reference symbol Nb in FIG. 4) arranged so as to be spaced apart from each other, and a control terminal for controlling the conduction between the first terminal electrode and the second terminal electrode. The first terminal and the second terminal of each of the TFTs 9a to 9g are conductor regions of the semiconductor layer 12a.

The first initialization TFT 9a is provided as an initialization TFT. As illustrated in FIG. 4, in each subpixel P, the control terminal of the first initialization TFT 9a is electrically connected to the corresponding gate line 14g, the first terminal electrode of the first initialization TFT 9a is electrically connected to the gate electrode 14a of the capacitor 9ha described later, and the second terminal electrode of the first initialization TFT 9a is electrically connected to the corresponding initialization power source line 16i. Here, the first initialization TFT 9a is configured to initialize a voltage applied to the control terminal of the drive TFT 9d by applying a voltage of the initialization power source line 16i to the capacitor 9ha. Note that the control terminal of the first initialization TFT 9a is electrically connected to the gate line 14g (n−1) that is scanned in a scan being the one before the scan of the gate line 14g (n) that is electrically connected to each of the control terminals of the threshold voltage compensation TFT 9b, the write control TFT 9c, and the second initialization TFT 9g.

The threshold voltage compensation TFT 9b is provided as a compensation TFT. As illustrated in FIG. 4, in each subpixel P, a control terminal of the threshold voltage compensation TFT 9b is electrically connected to the corresponding gate line 14g, the first terminal electrode of the threshold voltage compensation TFT 9b is electrically connected to the second terminal electrode of the drive TFT 9d, and the second terminal electrode of the threshold voltage compensation TFT 9b is electrically connected to the control terminal of the drive TFT 9d. Here, the threshold voltage compensation TFT 9b is configured to compensate the threshold voltage of the drive TFT 9d when the drive TFT 9d is set in a diode-connected state in response to the selection of the gate line 14g.

The write control TFT 9c is provided as a write TFT. As illustrated in FIG. 4, in each subpixel P, the control terminal of the write control TFT 9c is electrically connected to the corresponding gate line 14g, the first terminal electrode of the write control TFT 9c is electrically connected to the corresponding source line 18f, and the second terminal electrode of the write control TFT 9c is electrically connected to the first terminal electrode of the drive TFT 9d. Here, the write control TFT 9c is configured to apply a voltage of the source line 18f to the first terminal electrode of the drive TFT 9d, in response to the selection of the gate line 14g.

The drive TFT 9d is provided as a drive TFT. As illustrated in FIG. 4, in each subpixel P, the control terminal of the drive TFT 9d is electrically connected to the first terminal electrode of the first initialization TFT 9a and the second terminal electrode of the threshold voltage compensation TFT 9b, the first terminal electrode of the drive TFT 9d is electrically connected to each of the second terminal electrodes of the write control TFT 9c and the power source supply TFT 9e, and the second terminal electrode of the drive TFT 9d is electrically connected to each of the first terminal electrodes of the threshold voltage compensation TFT 9b and the light emission control TFT 9f. Here, the drive TFT 9d is configured to apply, to the first terminal electrode of the light emission control TFT 9f, a drive current corresponding to a voltage applied between the control terminal and the first terminal electrode of the drive TFT 9d, to control the amount of current in an organic EL element 25 described later.

Specifically, as illustrated in FIG. 3 and FIG. 6, the drive TFT 9d includes the semiconductor layer 12a, the gate insulating film 13, the gate electrode 14a (control terminal), the first interlayer insulating film 15, the second interlayer insulating film 17, the first terminal electrode 18a, and the second terminal electrode 18b, which are provided in order on the base coat film 11. Here, as illustrated in FIG. 5, the semiconductor layer 12a is substantially provided in an H-shape on the base coat film 11. As illustrated in FIG. 5, the semiconductor layer 12a includes a channel region (intrinsic region) 12ac provided so as to overlap with the gate electrode 14a in a plan view, and a first conductor region 12aa (dotted portion in FIG. 5) and a second conductor region 12ab (dotted portion in FIG. 5) provided with the channel region 12ac interposed therebetween. Note that, as illustrated in FIG. 5, an intermediate portion of the channel region 12ac is provided in a U-shape in a plan view, and the channel region 12ac includes a recessed portion C that is recessed downward in the drawing. One conductor region of the semiconductor layer 12a is provided as the first terminal electrode 18a, is formed integrally with the second terminals of the write control TFT 9c and the power source supply TFT 9e, and is electrically connected to the second terminals. The other conductor region of the semiconductor layer 12a is provided as the second terminal electrode 18b, is formed integrally with the first terminals of the threshold voltage compensation TFT 9b and the light emission control TFT 9f, and is electrically connected to the first terminals. As illustrated in FIG. 3 and FIG. 6, the gate insulating film 13 is provided so as to cover the semiconductor layer 12a. As illustrated in FIG. 5 (see also FIG. 3 and FIG. 6), the gate electrode 14a is provided in a rectangular island shape in a plan view on the gate insulating film 13 so as to overlap with the channel region 12ac of the semiconductor layer 12a. The first interlayer insulating film 15 is provided so as to cover the gate electrode 14a, as illustrated in FIG. 3 and FIG. 6. As illustrated in FIGS. 3, 5, and 6, the second interlayer insulating film 17 is provided on the first interlayer insulating film 15 with the capacitance electrode 16c described later interposed therebetween. As illustrated in FIG. 3, the first terminal electrode 18a and the second terminal electrode 18b are provided on the second interlayer insulating film 17 so as to be spaced apart from each other. As illustrated in FIG. 3, the first terminal electrode 18a and the second terminal electrode 18b are electrically connected to the first conductor region 12aa and the second conductor region 12ab of the semiconductor layer 12a (see FIG. 4), respectively, via respective contact holes formed in a layered film of the gate insulating film 13, the first interlayer insulating film 15, and the second interlayer insulating film 17.

The power source supply TFT 9e is provided as a power source supply TFT. As illustrated in FIG. 4, in each subpixel P, the control terminal of the power source supply TFT 9e is electrically connected to the corresponding light emission control line 14e, the first terminal electrode of the power source supply TFT 9e is electrically connected to the corresponding power source line 18g, and the second terminal electrode of the power source supply TFT 9e is electrically connected to the first terminal electrode of the drive TFT 9d. Here, the power source supply TFT 9e is configured to apply a voltage of the power source line 18g to the first terminal electrode of the drive TFT 9d, in response to the selection of the light emission control line 14e.

The light emission control TFT 9f is provided as a light emission control TFT. As illustrated in FIG. 4, in each subpixel P, the control terminal of the light emission control TFT 9f is electrically connected to the corresponding light emission control line 14e, the first terminal electrode of the light emission control TFT 9f is electrically connected to the second terminal electrode of the drive TFT 9d, and the second terminal electrode of the light emission control TFT 9f is electrically connected to a first electrode 21 of the organic EL element 25. Here, the light emission control TFT 9f is configured to apply the drive current to the organic EL element 25 in response to the selection of the light emission control line 14e.

Specifically, as illustrated in FIG. 3, the light emission control TFT 9f includes the semiconductor layer 12b, the gate insulating film 13, the gate electrode 14b (control terminal), the first interlayer insulating film 15, the second interlayer insulating film 17, the first terminal electrode 18c, and the second terminal electrode 18d, which are provided in order on the base coat film 11. Here, as illustrated in FIG. 3, the semiconductor layer 12b is provided in an island shape on the base coat film 11, and includes a channel region, and a first conductor region and a second conductor region provided with the channel region interposed therebetween. As illustrated in FIG. 3, the gate insulating film 13 is provided so as to cover the semiconductor layer 12b. As illustrated in FIG. 3, the gate electrode 14b is provided on the gate insulating film 13 so as to overlap with the channel region of the semiconductor layer 12b. As illustrated in FIG. 3, the first interlayer insulating film 15 and the second interlayer insulating film 17 are provided in order so as to cover the gate electrode 14b. As illustrated in FIG. 3, the first terminal electrode 18c and the second terminal electrode 18d are provided on the second interlayer insulating film 17 so as to be spaced apart from each other. As illustrated in FIG. 3, the first terminal electrode 18c and the second terminal electrode 18d are electrically connected to the first conductor region and the second conductor region of the semiconductor layer 12b, respectively, via respective contact holes formed in a layered film of the gate insulating film 13, the first interlayer insulating film 15, and the second interlayer insulating film 17.

Note that the first initialization TFT 9a, the threshold voltage compensation TFT 9b, the write control TFT 9c, the power source supply TFT 9e, and the second initialization TFT 9g have substantially the same configuration as that of the light emission control TFT 9f.

The second initialization TFT 9g is provided as an anode electrode discharge TFT. As illustrated in FIG. 4, in each pixel P, the control terminal of the second initialization TFT 9g is electrically connected to the corresponding gate line 14g, the first terminal electrode of the second initialization TFT 9g is electrically connected to the first electrode 21 of the organic EL element 25, and the second terminal electrode of the second initialization TFT 9g is electrically connected to the corresponding initialization power source line 16i. Here, the second initialization TFT 9g is configured to reset, in response to the selection of the gate line 14g, a charge accumulated in the first electrode 21 of the organic EL element 25.

Note that, in the present embodiment, there is provided an example where the TFTs 9a to 9g are top gate type TFTs, but the TFTs 9a to 9g may be bottom gate type TFTs.

As illustrated in FIGS. 3, 5, and 6, the capacitor 9ha includes the gate electrode 14a, the first interlayer insulating film 15 provided on the gate electrode 14a, and the capacitance electrode 16c (second metal layer) provided on the first interlayer insulating film 15 and arranged so as to overlap with the gate electrode 14a in a plan view. Note that, in the plan view of FIG. 5, the flattening film 19 illustrated in FIG. 3 and FIG. 6 is omitted. As illustrated in FIG. 4, in each subpixel P, the gate electrode 14a of the capacitor 9ha is integrally formed with the gate electrode 14a of the drive TFT 9d to be electrically connected to the gate electrode 14a of the drive TFT 9d, the first terminal electrode of the first initialization TFT 9a, and the second terminal electrode of the threshold voltage compensation TFT 9b, and the capacitance electrode 16c of the capacitor 9ha is electrically connected to the corresponding power source line 18g via a contact hole (not illustrated) formed in the first interlayer insulating film 15. Here, the capacitor 9ha is configured to be charged with the voltage of the corresponding source line 18f in a case where the corresponding gate line 14g is in a select state and to maintain the charged voltage, to thereby maintain the voltage applied to the control terminal of the drive TFT 9d in a case where the corresponding gate line 14g is in a non-select state. As illustrated in FIG. 5, the capacitance electrode 16c is provided over the entire circumference of a circumferential end (circumferential edge) of the gate electrode 14a, at an inner side of the circumferential end (up to a vicinity of the circumferential end). As illustrated in FIG. 5, the capacitance electrode 16c is provided so as to extend to an outer side of the circumferential end of the gate electrode 14a in a direction (a direction X illustrated in FIG. 5) substantially orthogonal to a line width direction (a direction Y illustrated in FIG. 5 and FIG. 6) of the capacitance electrode 16c. In other words, the capacitance electrode 16c extends in the direction X substantially orthogonal to the line width direction Y of the capacitance electrode 16c and is also arranged in a portion not overlapping with the gate electrode 14a in a plan view. As illustrated in FIG. 5, a width Wa of a portion of the capacitance electrode 16c overlapping with the gate electrode 14a in a plan view is larger than a width Wb of the portion of the capacitance electrode 16c not overlapping with the gate electrode 14a in a plan view. The capacitance electrode 16c is electrically connected to the corresponding power source line 18g in the portion not overlapping with the gate electrode 14a in a plan view. As illustrated in FIG. 5 and FIG. 6, the capacitance electrode 16c is provided with an opening M₁₆ (a second opening) overlapping with the gate electrode 14a in a plan view and extending through the capacitance electrode 16c. As illustrated in FIG. 5, the opening M₁₆ is provided so as to overlap with the recessed portion C of the semiconductor layer 12a in a plan view. The first interlayer insulating film 15 is exposed from the opening M₁₆.

As illustrated in FIGS. 3, 5, and 6, the capacitor 9ha includes the second interlayer insulating film 17 provided on the capacitance electrode 16c so as to cover the capacitance electrode 16c (and the opening M₁₆ of the capacitance electrode 16c). In other words, as illustrated in FIG. 5 and FIG. 6, the second interlayer insulating film 17 is provided on the first interlayer insulating film 15 or the capacitance electrode 16c. As illustrated in FIG. 5 and FIG. 6, the first interlayer insulating film 15 and the second interlayer insulating film 17 in the opening M₁₆ of the capacitance electrode 16c are provided with a contact hole H extending through the first interlayer insulating film 15 and the second interlayer insulating film 17 to expose the gate electrode 14a. Specifically, as illustrated in FIG. 5 and FIG. 6, the contact hole H is arranged at an inner side of the circumferential end of the opening M₁₆ of the capacitance electrode 16c in a plan view. As illustrated in FIG. 5 and FIG. 6, the connection wiring line 18e electrically connected to the gate electrode 14a via the contact hole H is provided on the second interlayer insulating film 17. As illustrated in FIG. 5 and FIG. 6, the connection wiring line 18e is provided in the recessed portion C of the semiconductor layer 12a so as to be orthogonal to the channel region 12ac of the semiconductor layer 12a, and is electrically connected to the corresponding gate line 14g.

In the present embodiment, as illustrated in FIG. 5 and FIG. 6, the capacitor 9ha further includes a capacitance wiring line 18ha (third metal layer) provided on the capacitance electrode 16c. The capacitor 9ha is illustrated in FIG. 5 and FIG. 6 having a large etching shift amount (difference between a resist pattern (design pattern) and a finished pattern) when a third metal film constituting the capacitance electrode 16c is formed and then patterned to form the capacitance electrode 16c. Specifically, the drawings illustrate the capacitor 9ha in which a line width (a length in the direction Y illustrated in FIG. 5 and FIG. 6) W₁₆, of the capacitance electrode 16c is reduced (due to the etching shift, the pattern of the capacitance electrode 16c is thinned in the direction Y with respect to the design pattern of the capacitance electrode 16c).

As illustrated in FIG. 5, the capacitance wiring line 18ha is provided so as to overlap with the gate electrode 14a and the capacitance electrode 16c in a plan view. Specifically, as illustrated in FIG. 5, the capacitance wiring line 18ha is provided along a circumferential end of the gate electrode 14a, at an inner side of the circumferential end. As illustrated in FIG. 5, the capacitance wiring line 18ha is provided along the circumferential end of the capacitance electrode 16c, up to an outer side of the circumferential end. Similarly to the capacitance electrode 16c, the capacitance wiring line 18ha extends in the direction X substantially orthogonal to the line width direction Y of the capacitance electrode 16c (the capacitance wiring line 18ha) and is also arranged in a portion not overlapping with the gate electrode 14a in a plan view. As illustrated in FIG. 5, the capacitance wiring line 18ha is provided over the entire circumference of the circumferential end of the opening M₁₆ of the capacitance electrode 16c, at an inner side of the circumferential end. As illustrated in FIG. 5, the capacitance wiring line 18ha is provided in an inverted U-shape in a plan view so as not to overlap with the connection wiring line 18e in a plan view along the circumferential end of the connection wiring line 18e.

As illustrated in FIG. 5 and FIG. 6, in a portion of the second interlayer insulating film 17 overlapping with the capacitance wiring line 18ha in a plan view, an opening M₁₆ (first opening) is provided extending through the second interlayer insulating film 17. Specifically, as illustrated in FIG. 5, the opening M₁₇ₐ is provided along the circumferential end of the gate electrode 14a, at an inner side of the circumferential end. As illustrated in FIG. 5, the opening M₁₇ₐ is provided along the circumferential end of the capacitance wiring line 18ha, up to an outer side of the circumferential end. That is, as illustrated in FIG. 5, the opening M₁₇ₐ is provided along the circumferential end of the capacitance electrode 16c arranged at an inner side of the capacitance wiring line 18ha, up to an outer side of the circumferential end. As illustrated in FIG. 5, the opening M₁₇ₐ is provided along a circumferential end of the contact hole H, at an outer side of the circumferential end, and along a circumferential end of the opening M₁₆ of the capacitance electrode 16c, at an inner side of the circumferential end. The capacitance electrode 16c or the first interlayer insulating film 15 is exposed from the opening M₁₇ₐ. Specifically, as illustrated in FIG. 5 and FIG. 6, the capacitance electrode 16c is not arranged in a portion at an outer side of the circumferential end of the capacitance electrode 16c, and thus, the first interlayer insulating film 15 is exposed from the opening M₁₇ₐ in the portion at an outer side of the circumferential end. Here, as illustrated in FIG. 5 and FIG. 6, the capacitance wiring line 18ha is provided on the capacitance electrode 16c in the opening M₁₇ₐ, so as to cover the capacitance electrode 16c.

Specifically, as illustrated in FIG. 6, in the opening M₁₇ₐ, the capacitance wiring line 18ha is provided on the capacitance electrode 16c and on the first interlayer insulating film 15 being at both ends of the capacitance electrode 16c in the line width direction Y. In other words, the capacitance wiring line 18ha in the opening M₁₇ₐ is formed (exist) in the same layer (on the same plane) as the capacitance electrode 16c. In still other words, in the opening M₁₇ₐ, the capacitance wiring line 18ha contacts a surface (an upper surface and a side surface) of the capacitance electrode 16c. Thus, the capacitance wiring line 18ha is electrically connected to the capacitance electrode 16c via the opening M₁₇ₐ. In other words, it is also possible to say that the opening M₁₇ₐ is a contact hole for electrically connecting the capacitance electrode 16c and the capacitance wiring line 18ha.

Thus, in the present embodiment, one capacitor 9ha is provided which includes the gate electrode 14a, the capacitance electrode 16c and the capacitance wiring line 18ha that are electrically connected via the opening M₁₇ₐ and have the same potential, and the first interlayer insulating film 15 arranged between the gate electrode 14a and the capacitance electrode 16c. A capacitance of a capacitor 9ha is formed between the gate electrode 14a and the capacitance electrode 16c and the capacitance wiring line 18ha arranged facing each other across the first interlayer insulating film 15.

Note that a line width W₁₄ₐ of the gate electrode 14a, a line width W_{16c} of the capacitance electrode 16c, and a line width W₁₈ₕ of the capacitance wiring line 18ha illustrated in FIG. 5 are not particularly limited, but according to the capacitors 9ha illustrated in FIG. 5 and FIG. 6, the line width W₁₄ₐ of the gate electrode 14a is about 20 μm, the line width W_{16c} of the capacitance electrode 16c is about 10 to 15 μm, and the line width W₁₈ₕ of the capacitance wiring line 18ha is about 15 μm.

The configuration of the capacitor 9ha will be described in more detail with reference to FIGS. 7 to 9 in which the connection wiring line 18e is omitted. In the cross-sectional views of FIG. 8 and FIG. 9, the resin substrate layer 10, the base coat film 11, the semiconductor layer 12a (12ac), the gate insulating film 13, and the flattening film 19 illustrated in FIG. 6 are omitted. It is possible to apply the capacitor 9ha to a capacitor electrically connected to a drive TFT, and also to apply to a capacitor not provided with the connection wiring line 18e illustrated in FIG. 5 and FIG. 6. As described above, the capacitor 9ha includes the gate electrode 14a, the first interlayer insulating film 15, the capacitance electrode 16c, and the capacitance wiring line 18ha. As illustrated in FIG. 8 and FIG. 9, the second interlayer insulating film 17 and the capacitance wiring line 18ha are arranged on the capacitance electrode 16c. Specifically, the capacitance wiring line 18ha is arranged on the capacitance electrode 16c with the second interlayer insulating film 17 interposed therebetween. In the second interlayer insulating film 17 interposed between the capacitance electrode 16c and the capacitance wiring line 18ha, as illustrated in FIGS. 7 to 9, the opening M₁₇ₐ extending through the second interlayer insulating film 17 in a thickness direction of the second interlayer insulating film 17 (vertical direction in the drawing) is formed along the circumferential end of the capacitance electrode 16c over the entire circumference of the circumferential end. In the opening M₁₇ₐ, as illustrated in FIG. 8 and FIG. 9, the capacitance electrode 16c and the capacitance wiring line 18ha contact each other. Thus, the capacitance wiring line 18ha is electrically connected to the capacitance electrode 16c via the opening M₁₇ₐ and has the same potential as the capacitance electrode 16c.

Here, in the capacitor 9ha, as illustrated in FIG. 8 and FIG. 9 (see also FIG. 5), in a portion where the gate electrode 14a, the capacitance electrode 16c, and the capacitance wiring line 18ha overlap with each other in a plan view, the line width W₁₈ₕ of the capacitance wiring line 18ha is equal to or greater than the line width W_{16c} of the capacitance electrode 16c and is equal to or less than the line width W₁₄ₐ of the gate electrode 14a. Note that, in the following description, the size relationship between the line widths W₁₄ₐ, W_{16c}, and W₁₈ₕ refers to the size relationship between the line widths W₁₄ₐ, W_{16c}, and W₁₈ₕ in the portion where the gate electrode 14a, the capacitance electrode 16c, and the capacitance wiring line 18ha overlap with each other in a plan view. More specifically, the line width₁₈ₕ of the capacitance wiring line 18ha is equal to or greater than the line width W_{18c} of the capacitance electrode 16c (after patterning) obtained in a later-described TFT layer forming step in which a second metal film constituting the capacitance electrode 16c is formed and then patterned to form the capacitance electrode 16c, and is substantially equal to a design value Wd of the line width W_{16c} of the capacitance electrode 16c (line width W₁₈ₕ of capacitance wiring line 18ha≈design value Wd of line width W_{16c} of capacitance electrode 16c≥line width W_{16c} of capacitance electrode 16c). As used herein, the design value Wd of the line width W_{16c} of the capacitance electrode 16c refers to a length in the direction Y of a resist pattern (designed pattern) of the capacitance electrode 16c. Specifically, the design value Wd refers to a design line width of the capacitance electrode 16c determined based on a design value of a size of an area of the capacitance electrode 16c overlapping with the gate electrode 14a in a plan view (that is, a design value of the capacitance of the capacitor 9ha). The design value Wd is equal to or greater than the line width W_{16c} of the capacitance electrode 16c after patterning and equal to or less than the line width W₁₄ₐ of the gate electrode 14a.

In the capacitor 9ha, in order to make the line width W₁₈ₕ of the capacitance wiring line 18ha substantially equal to the design value Wd of the line width W_{16c} of the capacitance electrode 16c, as illustrated in FIG. 8 and FIG. 9, a length L_{M17a} of an outer circumferential end of the opening M₁₇ₐ of the second interlayer insulating film 17 in the line width direction Y of the capacitance electrode 16c is equal to or greater than the line width W_{16c} of the capacitance electrode 16c, and is equal to or less than the line width W₁₄ₐ of the gate electrode 14a. Specifically, the length L_{M17a} in the direction Y at the outer circumferential end of the opening M₁₇ₐ is substantially equal to the design value Wd of the line width W_{16c} of the capacitance electrode 16c. That is, as illustrated in FIG. 8 and FIG. 9, the length L_{M17a} in the direction Y at the outer circumferential end of the opening M₁₇ₐ is substantially equal to the line width W₁₈ₕ of the capacitance wiring line 18ha.

Thus, in the capacitor 9ha, when an etching shift occurs (an etching shift amount is large) and the line width W_{16c} of the capacitance electrode 16c is smaller than the design value Wd (W_{16c}<Wd), as illustrated in FIG. 8, a region where the capacitance electrode 16c does not exist (hereinafter also referred to as a “capacitance electrode 16c non-existing region”) is formed on at least one side of the capacitance electrode 16c in the line width direction Y (in FIG. 8, at an outer side of both ends of the capacitance electrode 16c in the direction Y). In the opening M₁₇ₐ, the first interlayer insulating film 15 is exposed from the capacitance electrode 16c non-existing region formed between the outer circumferential end of the opening M₁₇ₐ and the outer circumferential end of the capacitance electrode 16c, and the capacitance wiring line 18ha is arranged on the first interlayer insulating film 15. That is, the capacitance wiring line 18ha in the capacitance electrode 16c non-existing region in the opening M₁₇ₐ is formed in the same layer as the capacitance electrode 16c. As a result, as illustrated in FIG. 8, the sum of the line width W₁ of the capacitance electrode 16c and a line width (W₁₈ₕ-W_{16c}) of the capacitance wiring line 18ha in the portion formed in the same layer as the capacitance electrode 16c is equal to or less than the line width W₁₄ₐ of the gate electrode 14a, and is substantially equal to the line width W₁₈ₕ of the capacitance wiring line 18ha. Here, as described above, the line width W₁₈ₕ of the capacitance wiring line 18ha is substantially equal to the length L_{M17a} at the outer circumferential end of the opening M₁₇ₐ in the direction Y, that is, substantially equal to the design value Wd of the line width W_{16c} of the capacitance electrode 16c, and thus, a line width of a composite electrode composed of the capacitance electrode 16c and the capacitance wiring line 18ha formed in the same layer is substantially equal to the design value Wd of the line width W_{16c} of the capacitance electrode 16c. Therefore, the area of the above-described composite electrode overlapping with the gate electrode 14a in a plan view is substantially equal to the design value (design area) of the area of the capacitance electrode 16c overlapping with the gate electrode 14a in a plan view. Therefore, it is possible to suppress a capacitance change of the capacitor 9ha, and secure the design value of the capacitance designed in advance.

When only a substantially negligible amount of etching shift occurs (the etching shift amount is small) and the line width W_{16c} of the capacitance electrode 16c is substantially equal to the design value Wd thereof (W_{16c}≈Wd), as illustrated in FIG. 9, the capacitance electrode 16c non-existing region is not formed in the opening M₁₇ₐ. Therefore, the capacitance wiring line 18ha in the opening M₁₇ₐ is formed only on the capacitance electrode 16c, as illustrated in FIG. 9. As a result, as illustrated in FIG. 9, the line width W₁₈ₕ of the capacitance wiring line 18ha is substantially equal to and not greater than the line width Wu& of the capacitance electrode 16c (the design value Wd of the line width W_{16c} of the capacitance electrode 16c). In other words, when the line width W_{16c} of the capacitance electrode 16c is substantially equal to the design value Wd, the line width W₁₈ₕ of the capacitance wiring line 18ha does not affect a size of the line width W_{16c} of the capacitance electrode 16c. Therefore, the area of the capacitance electrode 16c and the capacitance wiring line 18ha overlapping with the gate electrode 14a in a plan view is substantially equal to the design area mentioned above. That is, in a case where the etching shift amount is small, the capacitance wiring line 18ha hardly affects the capacitance of the capacitor 9ha. Therefore, also in this case, it is possible to suppress a capacitance change of the capacitor 9ha, and secure the design value of the capacitance designed in advance.

In the capacitor 9ha configured as described above, when the line width W_{16c} of the capacitance electrode 16c is smaller than the design value Wd (W_{16c}<Wd), the capacitance wiring line 18ha is formed in the same layer as the capacitance electrode 16c in the opening M₁₇ₐ, and the line width W_{16c} of the capacitance electrode 16c is substantially equal to the design value Wd thereof (W_{16c}+α(a part of the line width W₁₈ₕ of the capacitance wiring line 18ha)≈Wd). When the line width W_{16c} of the capacitance electrode 16c is substantially equal to the design value Wd thereof (W_{16c}≈Wd), the capacitance wiring line 18ha does not affect the line width W_{16c} of the capacitance electrode 16c. Therefore, regardless of whether the line width W_{16c} of the capacitance electrode 16c is reduced, the line width (W_{16c} or W₁₈ₕ) of one electrode (that is, the capacitance electrode 16c and the capacitance wiring line 18ha) constituting the capacitor 9ha is equal to or less than the line width W₁₄ₐ of the gate electrode 14a, and is substantially equal to the design value Wd of the line width W_{16c} of the capacitance electrode 16c. This suppresses a capacitance change of the capacitor 9ha caused by variations in the line width W_{16c} of the capacitance electrode 16c.

The flattening film 19 has a flat surface in the display region D. The flattening film 19 is formed of, for example, an organic resin material such as a polyimide resin and an acrylic resin.

As illustrated in FIG. 3, the organic EL element layer 30 includes a plurality of the organic EL elements 25 corresponding to the plurality of pixel circuits C and being provided as a plurality of light-emitting elements arrayed in a matrix shape on the flattening film 19.

As illustrated in FIG. 3, the organic EL elements 25 each include the first electrode 21 provided on the flattening film 19, the organic EL layer 23 provided on the first electrode 21, and a second electrode 24 provided on the organic EL layer 23 so as to be common in the entire display region D.

As illustrated in FIG. 3, the first electrode 21 is electrically connected to the second terminal electrode of the light emission control TFT 9f of each of the subpixels P, via a contact hole formed in the flattening film 19. In addition, the first electrode 21 has a function of injecting holes (positive holes) into the organic EL layer 23. In addition, the first electrode 21 is preferably formed of a material with a high work function to improve the efficiency of hole injection into the organic EL layer 23. Here, examples of a material constituting the first electrode 21 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Examples of the material constituting the first electrode 21 may include alloys such as astatine (At)/astatine oxide (AtO₂). Furthermore, the material constituting the first electrode 21 may be electrically conductive oxide, for example, tin oxide (SnO), zinc oxide (ZnO), indium tin oxide (ITO), or indium zinc oxide (IZO). In addition, the first electrode 21 may be formed by layering a plurality of layers formed of any of the materials described above. Note that, examples of compound materials having a high work function include indium tin oxide (ITO) and indium zinc oxide (IZO).

A peripheral edge portion of the first electrode 21a is covered with an edge cover 22 provided so as to be common to the plurality of subpixels P in a lattice pattern in the entire display region D. Here, examples of a material constituting the edge cover 22 include a positive-working photosensitive resin such as a polyimide resin, an acrylic resin, a polysiloxane resin, and a novolac resin.

As illustrated in FIG. 10, the organic EL layer 23 is arranged on the first electrode 21 and provided as a light-emitting layer in a matrix shape so as to correspond to the plurality of subpixels P. The organic EL layer 23 includes a hole injection layer 1, a hole transport layer 2, a light-emitting layer 3, an electron transport layer 4, and an electron injection layer 5 that are provided in order on the first electrode 21.

The hole injection layer 1 is also referred to as an anode electrode buffer layer, and has a function of reducing an energy level difference between the first electrodes 21 and the organic EL layers 23 to thereby improve the efficiency of hole injection into the organic EL layers 23 from the first electrodes 21. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function of improving the efficiency of hole transport from the first electrodes 21 to the organic EL layers 23. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons are injected from the first electrode 21 and the second electrode 24, respectively, and the holes and the electrons recombine, when a voltage is applied via the first electrode 21 and the second electrode 24. Here, the light-emitting layer 3 is formed of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of facilitating migration of electrons to the light-emitting layer 3 efficiently. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 has a function of reducing an energy level difference between the second electrode 24 and the organic EL layer 23 to thereby improve the efficiency of electron injection into the organic EL layer 23 from the second electrode 24, and the electron injection layer 5 can lower the drive voltage of the organic EL element 25 by this function. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As illustrated in FIG. 3, the second electrode 24 is provided so as to cover the organic EL layer 23 of each of the subpixels P and the edge cover 22 common to all the subpixels P. In addition, the second electrode 24 has a function of injecting electrons into the organic EL layer 23. In addition, the second electrode 24 is preferably formed of a material with a low work function to improve the efficiency of electron injection into the organic EL layer 23. Here, examples of materials constituting the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The second electrode 24 may also be formed of an alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al), for example. In addition, the second electrode 24 may be formed of electrically conductive oxide, for example, tin oxide (SnO), zinc oxide (ZnO), indium tin oxide (ITO), indium zinc oxide (IZO), or the like. In addition, the second electrode 24 may be formed by layering a plurality of layers formed of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIG. 3, the sealing film 35 includes a first sealing inorganic insulating film 31 provided so as to cover the second electrode 24, a sealing organic film 32 provided on the first sealing inorganic insulating film 31, and a second sealing inorganic insulating film 33 provided so as to cover the sealing organic film 32, and has a function of protecting the organic EL layer 23 from moisture, oxygen, and the like. Here, the first sealing inorganic insulating film 31 and the second sealing inorganic insulating film 33 are each formed of, for example, an inorganic material such as silicon oxide (SiO₂), aluminum oxide (Al₂O₃), silicon nitride (SiNx (x is a positive number)) such as trisilicon tetranitride (Si₃N₄), and silicon carbonitride (SiCN). Further, the sealing organic film 32 is formed of, for example, an organic material such as an acrylic resin, a polyurea resin, a parylene resin, a polyimide resin, and a polyamide resin.

In the organic EL display device 50a having the configuration described above, in each subpixel P, first, the organic EL element 25 is brought into a non-light emission state when the corresponding light emission control line 14e is selected and deactivated. In the non-light emission state, the corresponding gate line 14g (which is electrically connected to the first initialization TFT 9a and the second initialization TFT 9g) is selected, and a gate signal is input to the first initialization TFT 9a via the gate line 14g, so that the first initialization TFT 9a and the second initialization TFT 9g are brought into an on state, a voltage of the corresponding initialization power source line 16i is applied to the capacitor 9ha, and the drive TFT 9d is brought into the on state. Thus, the charge of the capacitor 9ha is discharged to initialize the voltage applied to the control terminal (the gate electrode 14a) of the drive TFT 9d. Next, the corresponding gate line 14g (which is electrically connected to the threshold voltage compensation TFT 9b and the write control TFT 9c) is selected and activated, so that the threshold voltage compensation TFT 9b and the write control TFT 9c are brought into the on state. A predetermined voltage corresponding to a source signal transmitted via the corresponding source line 18f is written to the capacitor 9ha via the drive TFT 9d in the diode-connected state and an initialization signal is applied to the first electrode 21 of the organic EL element 25 via the corresponding initialization power source line 16i to reset the charge accumulated in the first electrode 21. Thereafter, the corresponding light emission control line 14e is selected, and the power source supply TFT 9e and the light emission control TFT 9f are brought into the on state, so that a drive current corresponding to the voltage applied to the control terminal of the drive TFT 9d is supplied to the organic EL element 25 from the corresponding power source line 18g. Thus, in each subpixel P in the organic EL display device 50a, the organic EL element 25 emits light at a luminance corresponding to the drive current, and an image is displayed.

Next, a method for manufacturing the organic EL display device 50a according to the present embodiment will be described. Note that the method for manufacturing the organic EL display device 50a according to the present embodiment includes a TFT layer forming step, an organic EL element layer forming step, and a sealing film forming step.

### TFT Layer Forming Step

### Base Coat Film Forming Step

First, for example, an inorganic insulating film (having a thickness of about 1000 nm) such as a silicon oxide film is formed on the resin substrate layer 10 formed on a glass substrate (not illustrated), for example, by a plasma chemical vapor deposition (CVD) method, to form the base coat film 11.

### Semiconductor Layer Forming Step

Subsequently, for example, an amorphous silicon film (thickness of approximately 50 nm) is formed on the entire substrate on which the base coat film 11 is formed, by plasma CVD, the amorphous silicon film is crystallized by laser annealing or the like to form a semiconductor film of a polysilicon film, and then, the semiconductor film is patterned to form the semiconductor layer 12a and the like.

### Gate Insulating Film Forming Step

Thereafter, an inorganic insulating film (having a thickness of about 100 nm) such as a silicon oxide film is formed on the entire substrate (on the semiconductor layer 12a or the like) on which the semiconductor layer 12a and the like is formed, for example, by plasma CVD, to form the gate insulating film 13 to cover the semiconductor layer 12a and the like.

### First Metal Layer Forming Step

Furthermore, a metal single layer film such as a molybdenum nitride film (first metal film having a thickness of about 260 nm) is formed, for example, by a sputtering method, on the entire substrate (on the gate insulating film 13) on which the gate insulating film 13 is formed, and then, the first metal film is patterned to form a first metal layer such as the gate electrode 14a (line width W₁₄ₐ: about 20 μm).

### Doping Step

Subsequently, the semiconductor layer 12a and the like including the first conductor region 12aa, the second conductor region 12ab, and the channel region 12ac is formed by doping with impurity ions using the first metal layer such as the gate electrode 14a as a mask.

### First Interlayer Insulating Film Forming Step

Thereafter, an inorganic insulating film (having a thickness of about 100 nm) such as a silicon nitride film is formed, for example, by plasma CVD, on the entire substrate on which the semiconductor layer 12a and the like is formed, to form the first interlayer insulating film 15.

### Second Metal Layer Forming Step

Subsequently, a metal single layer film such as a molybdenum nitride film (second metal film having a thickness of about 260 nm) is formed, for example, by a sputtering method, on the entire substrate on which the first interlayer insulating film 15 is formed, and then, the second metal film is patterned to form a second metal layer such as the initialization power source line 16i and the capacitance electrode 16c having the opening M₁₆. Here, the capacitance electrode 16c is arranged over the entire circumference of the circumferential end of the gate electrode 14a, at an inner side of the circumferential end, and the second metal film is patterned so as to have a line width W_{16c} of about 10 to 15 μm.

### Second Interlayer Insulating Film Forming Step

Furthermore, an inorganic insulating film such as a silicon nitride film (having a thickness of about 190 nm) and a silicon oxide film (having a thickness of about 270 nm) are formed in order, for example, by plasma CVD, on the entire substrate on which the second metal layer such as the capacitance electrode 16c is formed, to form the second interlayer insulating film 17. Thereafter, a layered film of the first interlayer insulating film 15 and the second interlayer insulating film 17 is patterned to form the second interlayer insulating film 17 including the contact hole H.

### First Opening Forming Step

Thereafter, the second interlayer insulating film 17 is patterned to form the opening M₁₇ₐ extending through the second interlayer insulating film 17. Specifically, the second interlayer insulating film 17 is etched along the circumferential end of the capacitance electrode 16c and the opening M₁₆ of the capacitance electrode 16c, to form the opening M₁₇ₐ from which the capacitance electrode 16c or the first interlayer insulating film 15 is exposed. At this time, the length L_{M17a} in the direction Y at the outer circumferential end of the opening M₁₇ₐ is adjusted to be equal to or less than the line width W₁₄ₐ of the gate electrode 14a (specifically, substantially equal to the design value Wd of the line width W_{16c} of the capacitance electrode 16c).

### Third Metal Layer Forming Step

Subsequently, a titanium film (having a thickness of about 10 to 100 nm), an aluminum film (having a thickness of about 300 to 700 nm), a titanium film (having a thickness of about 10 to 100 nm), and the like are formed in order, for example, by a sputtering method, on the entire substrate on which the contact hole H and the opening M₁₇ₐ are formed, and then, the Ti/Al/Ti metal layered film (third metal film) is patterned to form a third metal layer such as the connection wiring line 18e, the source line 18f, the power source line 18g, and the capacitance wiring line 18ha. Here, the third metal film is patterned so that the capacitance wiring line 18ha is arranged on the capacitance electrode 16c, overlapping with the capacitance electrode 16c and the gate electrode 14a in a plan view, and being arranged along the circumferential end of the gate electrode 14a, at an inner side of the circumferential end. At this time, the line width W₁₈ₕ of the capacitance wiring line 18ha is adjusted to about 15 μm so as to be equal to or greater than the line width W_{16c} of the capacitance electrode 16c and equal to or less than the line width W₁₄ₐ of the gate electrode 14a (specifically, substantially equal to the design value Wd of the line width W_{16c} of the capacitance electrode 16c).

### Flattening Film Forming Step

Finally, a polyimide-based photosensitive resin film (having a thickness of about 2 μm) is applied by, for example, a spin coating method or a slit coating method to the entire substrate on which the third metal layer such as the connection wiring line 18e and the capacitance wiring line 18ha is formed, and then, the applied film is pre-baked, exposed, developed, and post-baked to form the flattening film 19.

Thus, the TFT layer 20a can be formed as described above.

### Organic EL Element Layer Forming Step

The organic EL element layer 30 is formed by forming, by a known method, the first electrode 21, the edge cover 22, the organic EL layer 23 (the hole injection layer 1, the hole transport layer 2, the light-emitting layer 3, the electron transport layer 4, the electron injection layer 5), and the second electrode 24 on the flattening film 19 of the TFT layer 20a formed in the TFT layer forming step described above.

### Sealing Film Forming Step

The sealing film 35 (the first sealing inorganic insulating film 31, the sealing organic film 32, and the second sealing inorganic insulating film 33) is formed, by using a known method, on the organic EL element layer 30 formed in the organic EL element layer forming step described above. Thereafter, a protective sheet (not illustrated) is bonded to a substrate surface on which the sealing film 35 is formed, and then, laser light is emitted from the glass substrate side of the resin substrate layer 10 so that the glass substrate peels off from a lower surface of the resin substrate layer 10, and furthermore, a protective sheet (not illustrated) is bonded to the lower surface of the resin substrate layer 10 from which the glass substrate has peeled off.

Thus, the organic EL display device 50a of the present embodiment can be manufactured as described above.

As described above, according to the organic EL display device 50a of the present embodiment, the following effects can be obtained.

(1) In the organic EL display device 50a, one capacitor 9ha (gate electrode 14a/first interlayer insulating film 15/capacitance electrode 16c/and capacitance wiring line 18ha) is formed by the gate electrode 14a, the capacitance electrode 16c and the capacitance wiring line 18ha that are electrically connected to each other, and the first interlayer insulating film 15 arranged between the gate electrode 14a and the capacitance electrode 16c. In the capacitor 9ha, the line width W₁₈ₕ of the capacitance wiring line 18ha is equal to or greater than the line width W_{16c} of the capacitance electrode 16c and equal to or less than the line width W₁₄, of the gate electrode 14a. Thus, even when the line width W_{16c} of the capacitance electrode 16c formed in the TFT layer forming step is smaller than the design value Wd thereof, the capacitance wiring line 18ha compensates and maintains the line width W_{16c} substantially equal to the design value Wd. As a result, it is possible to suppress a capacitance change of the capacitor 9ha caused by a decrease in the line width W_{16c} of the capacitance electrode 16c.

(2) In the organic EL display device 50a, when the line width W_{16c} of the capacitance electrode 16c is not smaller than the design value Wd thereof, the capacitance wiring line 18ha does not affect the line width W_{16c} (the design value Wd) of the capacitance electrode 16c (the line width W₁₈ₕ of the capacitance wiring line 18ha is not greater than the line width W₁₄ₐ of the gate electrode 14a). Therefore, even in this case, it is possible to suppress the capacitance change of the capacitor 9ha.

(3) In the organic EL display device 50a, by the effects of (1) and (2) described above, the capacitance change (variation) of the capacitor 9ha caused by the variation in the line width W_{16c} of the capacitance electrode 16c is reduced (suppressed), so that display unevenness (irregularity) is less likely to be observed during panel display, and as a result, the quality of the panel display can be improved.

### Second Embodiment

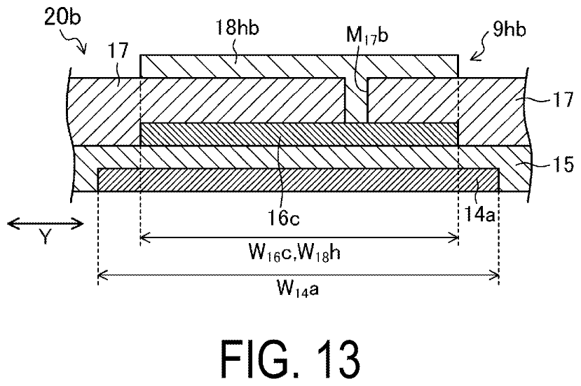

Next, a second embodiment of the present invention will be described. FIGS. 11 to 13 illustrate a second embodiment of the display device according to the present invention. FIG. 11 is a plan view schematically illustrating a capacitor 9hb included in a TFT layer 20b of an organic EL display device 50b according to the present embodiment, and corresponds to FIG. 7. Further, FIG. 12 is a cross-sectional view schematically illustrating the capacitor 9hb, taken along line B-B in FIG. 11, illustrates a state where the line width of the capacitance electrode 16c included in the capacitor 9hb is reduced, and corresponds to FIG. 8. Further, FIG. 13 is a cross-sectional view schematically illustrating the capacitor 9hb, taken along line B-B in FIG. 11, illustrates a state where the line width of the capacitance electrode 16c included in the capacitor 9hb is not reduced, and corresponds to FIG. 9.

The entire configuration of the organic EL display device 50b, except for the capacitor 9hb, is the same as that of the above-described first embodiment, and detailed description thereof will be omitted here. Note that constituent portions similar to those in the first embodiment are denoted by the same reference signs, and a description thereof will be omitted.

The capacitor 9hb includes the gate electrode 14a, the first interlayer insulating film 15, the capacitance electrode 16c, the second interlayer insulating film 17, and a capacitance wiring line 18hb (third metal layer). As illustrated in FIG. 12 and FIG. 13, the second interlayer insulating film 17 is provided on the capacitance electrode 16c so as to cover the capacitance electrode 16c. As illustrated in FIG. 12 and FIG. 13, the second interlayer insulating film 17 is provided with the capacitance wiring line 18hb. Specifically, the capacitance wiring line 18hb is arranged on the capacitance electrode 16c with the second interlayer insulating film 17 interposed therebetween. When the connection wiring line 18e is arranged on the second interlayer insulating film 17, a portion of the capacitance wiring line 18hb overlapping with the capacitance electrode 16c may be provided in a U-shape so as not to overlap with the connection wiring line 18e in a plan view, similarly to the capacitance wiring line 18ha illustrated in FIG. 5. That is, it is also possible to apply the capacitor 9hb to a capacitor electrically connected to a drive TFT.

Here, in the capacitor 9hb, as illustrated in FIGS. 11 to 13, unlike the opening M₁₇ₐ of the second interlayer insulating film 17 included in the capacitor 9ha, in a portion of the second interlayer insulating film 17 overlapping with the capacitance wiring line 18hb in a plan view, an opening M_{17b} (first opening) is provided in a hole shape extending through the second interlayer insulating film 17 in a thickness direction thereof (vertical direction in the drawing). The capacitance electrode 16c is exposed from the hole-shaped opening M_{17b}. In the opening M_{17b}, as illustrated in FIG. 12 and FIG. 13, the capacitance electrode 16c and the capacitance wiring line 18hb contact each other. Thus, the capacitance wiring line 18hb is electrically connected to the capacitance electrode 16c via the opening M_{17b} and has the same potential as the capacitance electrode 16c. In other words, it is also possible to say that the opening M_{17b} is a contact hole for electrically connecting the capacitance electrode 16c and the capacitance wiring line 18hb. The arrangement of the opening M_{17b} of the second interlayer insulating film 17 is not particularly limited, as long as the opening M_{17b} is arranged in a portion where the capacitance electrode 16c and the capacitance wiring line 18hb overlap with each other in a plan view, and may be appropriately determined in accordance with the arrangement of another electrode and the like.

As described above, one capacitor 9hb is constituted by the gate electrode 14a, the capacitance electrode 16c, the capacitance wiring line 18hb (having the same potential as the capacitance electrode 16c) electrically connected to the capacitance electrode 16c, and the first interlayer insulating film 15 interposed between the gate electrode 14a and the capacitance electrode 16c.

Here, in the capacitor 9hb, as illustrated in FIG. 12 and FIG. 13, similarly to the capacitor 9ha, the line width W₁₈ₕ of the capacitance wiring line 18hb is equal to or greater than the line width W_{16c} of the capacitance electrode 16c and equal to or less than the line width W₁₄ₐ of the gate electrode 14a (specifically, substantially equal to the design value Wd of the line width W_{16c} of the capacitance electrode 16c). Thus, in the capacitor 9hb, when the etching shift amount is large, and as illustrated in FIG. 12, the line width W_{16c} of the formed capacitance electrode 16c is smaller than the design value Wd thereof (W_{16c}<Wd), the capacitance electrode 16c non-existing region is formed on at least one side in the line width direction Y of the capacitance electrode 16c that is smaller than the design value Wd (in FIG. 12, on the left side in the direction Y of the capacitance electrode 16c that is smaller than design value Wd). As illustrated in FIG. 12, the capacitance wiring line 18hb is arranged on the gate electrode 14a in the capacitance electrode 16c non-existing region, with the first interlayer insulating film 15 and the second interlayer insulating film 17 interposed between the capacitance wiring line 18hb and the gate electrode 14a. That is, in the capacitance electrode 16c non-existing region, instead of the capacitance electrode 16c, the capacitance wiring line 18hb having the same potential as the capacitance electrode 16c is provided so as to overlap with the gate electrode 14a in a plan view. Thus, in the capacitance electrode 16c non-existing region, a part of the capacitance of the capacitor 9hb is formed between the capacitance wiring line 18hb and the gate electrode 14a that are arranged facing each other across the first interlayer insulating film 15 (and the second interlayer insulating film 17). As a result, as illustrated in FIG. 12, the sum of the line width W_{16c} of the capacitance electrode 16c and the line width (W₁₈ₕ-W_{16c}) of the capacitance wiring line 18hb in the capacitance electrode 16c non-existing region is equal to or less than the line width W₁₄ₐ of the gate electrode 14a, and substantially equal to the line width W₁₈ₕ of the capacitance wiring line 18hb. Here, as described above, the line width W₁₈ₕ of the capacitance wiring line 18hb is substantially equal to the design value Wd of the line width W_{16c} of the capacitance electrode 16c, and thus, the line width of a composite electrode constituted by the capacitance electrode 16c and the capacitance wiring line 18hb arranged in the capacitance electrode 16c non-existing region is substantially equal to the design value Wd of the line width W_{16c} of the capacitance electrode 16c. Therefore, the area of the above-described composite electrode overlapping with the gate electrode 14a in a plan view is substantially equal to the design area mentioned above. Therefore, it is possible to suppress a capacitance change of the capacitor 9hb, and secure the design value of the capacitance designed in advance.

When the etching shift amount is small and the line width W_{16c} of the capacitance electrode 16c is substantially equal to the design value Wd thereof (W_{16c}≈Wd), the capacitance electrode 16c non-existing region is not formed, as illustrated in FIG. 13. As a result, as illustrated in FIG. 13, the line width W₁₈ₕ of the capacitance wiring line 18hb is substantially equal to the line width W_{16c} of the capacitance electrode 16c and does not affect the size of the line width W_{16c}. Therefore, the area of the capacitance electrode 16c overlapping with the gate electrode 14a in a plan view is substantially equal to the design area mentioned above. That is, in a case where the etching shift amount is small, the capacitance wiring line 18hb hardly affects the capacitance of the capacitor 9hb. Therefore, also in this case, it is possible to suppress a capacitance change of the capacitor 9hb, and secure the design value of the capacitance designed in advance.

Also in the capacitor 9hb configured as described above, when the line width W_{16c} of the capacitance electrode 16c is smaller than the design value Wd thereof (W₁₆<Wd), a part of the capacitance of the capacitor 9hb is formed between the capacitance wiring line 18hb and the gate electrode 14a in the capacitance electrode 16c non-existing region, and the line width W_{16c} of the capacitance electrode 16c is substantially equal to the design value Wd thereof. When the line width W_{16c} of the capacitance electrode 16c is substantially equal to the design value Wd thereof (W_{16c}≈Wd), the capacitance wiring line 18hb does not affect the line width W_{16c} of the capacitance electrode 16c. This suppresses a capacitance change of the capacitor 9hb caused by variations in the line width W_{16c} of the capacitance electrode 16c.

For example, the organic EL display device 50b can be manufactured by changing, as described below, the first opening forming step in the TFT layer forming step in the method for manufacturing the organic EL display device 50a of the above-described first embodiment.

### First Opening Forming Step

The organic EL display device 50b can be manufactured by changing a pattern shape of the opening M₁₇ₐ when etching the second interlayer insulating film 17. Specifically, the second interlayer insulating film 17 is etched in a hole shape in a portion where the capacitance electrode 16c and the capacitance wiring line 18hb overlap with each other in a plan view, to form the opening M_{17b} having a hole shape from which the capacitance electrode 16c is exposed.

Thus, the organic EL display device 50b of the present embodiment can be manufactured as described above.

As described above, according to the organic EL display device 50b of the present embodiment, it is possible to obtain an effect similar to that of the organic EL display device 50a of the above-described first embodiment.

### OTHER EMBODIMENTS

In the embodiments described above, an example of the organic EL layer including a five-layer structure including the hole injection layer, the hole transport layer, the light-emitting layer, the electron transport layer, and the electron injection layer is given. However, the organic EL layer may, for example, include a three-layer structure including a hole injection-cum-transport layer, a light-emitting layer, and an electron transport-cum-injection layer.

In the embodiments described above, an example of the organic EL display device including the first electrode as an anode electrode and the second electrode as a cathode electrode is given. However, the present invention is also applicable to an organic EL display device in which the layers of the structure of the organic EL layer are in a reversed order, with the first electrode being a cathode electrode and the second electrode being an anode electrode.

In each of the embodiments described above, the organic EL display device in which the electrode of the TFT connected to the first electrode serves as the drain electrode is exemplified. However, the present invention is also applicable to an organic EL display device in which the electrode of the TFT connected to the first electrode is referred to as the source electrode.

Although the foregoing embodiments describe organic EL display devices as examples of display devices, the present invention may be applied in display devices including a plurality of light-emitting elements that are driven by an electrical current. For example, the present invention is applicable to a display device including quantum-dot light emitting diodes (QLEDs) that are light-emitting elements using a quantum dot-containing layer.

### INDUSTRIAL APPLICABILITY

As described above, the present invention is useful for a flexible display device.

### REFERENCE SIGNS LIST

C Recessed portion
H Contact hole
L_{M17a} Length of outer circumferential end of opening (first opening) of second interlayer insulating film
M₁₆ Opening of capacitance electrode (second opening)
M₁₇ₐ, M_{17b} Opening of second interlayer insulating film (first opening)
W₁₄ₐ Line width of gate electrode
W_{16c} Line width of capacitance electrode
W₁₈ₕ Line width of capacitance wiring line
9a Drive TFT (drive thin film transistor)
9ha, 9hb Capacitor
10 Resin substrate layer (base substrate)
12a, 12b Semiconductor layer
12aa First conductor region
12ab Second conductor region
12ac Channel region
13 Gate insulating film
14a, 14b Gate electrode
15 First interlayer insulating film
16c Capacitance electrode
17 Second interlayer insulating film
18e Connection wiring line
18ha, 18hb Capacitance wiring line
20a, 20b TFT layer (thin film transistor layer)
25 Organic EL element (organic electroluminescence element, light-emitting element)
30 Organic EL element layer (light-emitting element layer)
50a, 50b Organic EL display device

1. A display device comprising:
a base substrate;
a thin film transistor layer provided with a semiconductor layer, a gate insulating film, a first metal layer, a first interlayer insulating film, a second metal layer, a second interlayer insulating film, and a third metal layer, in order, on the base substrate, and including a thin film transistor and a capacitor arranged for each of subpixels; and
a light-emitting element layer provided on the thin film transistor layer and including a light-emitting element arranged for each of the subpixels,
the thin film transistor including the semiconductor layer, the gate insulating film covering the semiconductor layer, and a gate electrode provided as the first metal layer on the gate insulating film and arranged in an island shape overlapping with a part of the semiconductor layer in a plan view,
wherein the capacitor includes the gate electrode, the first interlayer insulating film provided on the gate electrode, a capacitance electrode provided as the second metal layer on the first interlayer insulating film and overlapping with the gate electrode in a plan view, and a capacitance wiring line provided as the third metal layer on the capacitance electrode and overlapping with the capacitance electrode and the gate electrode in a plan view,
the capacitance wiring line is electrically connected to the capacitance electrode,
a capacitance of the capacitor is formed between the gate electrode and the capacitance electrode and the capacitance wiring line facing each other across the first interlayer insulating film, and
a line width of the capacitance wiring line is equal to or greater than a line width of the capacitance electrode and equal to or less than a line width of the gate electrode.

2. The display device according to claim 1,
wherein the capacitance wiring line is provided along a circumferential end of the gate electrode, at an inner side of the circumferential end, and
the capacitance electrode is provided along a circumferential end of the capacitance wiring line, at an inner side of the circumferential end.

3. The display device according to claim 1,
wherein a first opening overlapping with the capacitance wiring line in a plan view and extending through the second interlayer insulating film is provided in the second interlayer insulating film, and
the first opening is provided along a circumferential end of the capacitance electrode, and the capacitance electrode or the first interlayer insulating film is exposed from the first opening.

4. The display device according to claim 3,
wherein a length of an outer circumferential end of the first opening in a line width direction of the capacitance electrode is equal to or greater than the line width of the capacitance electrode and equal to or less than the line width of the gate electrode.

5. The display device according to claim 3,
wherein the first interlayer insulating film is exposed from the first opening, and in the first opening, the capacitance wiring line is formed in the same layer as the capacitance electrode.

6. The display device according to claim 5,
wherein a sum of the line width of the capacitance electrode and the line width of the capacitance wiring line in a portion formed in the same layer as the capacitance electrode is equal to or less than the line width of the gate electrode.

7. The display device according to claim 1,
wherein a first opening overlapping with the capacitance wiring line in a plan view and extending through the second interlayer insulating film is provided in the second interlayer insulating film, and
the first opening is provided in a hole shape and the capacitance electrode is exposed from the first opening.

8. The display device according to claim 7,
wherein a portion not overlapping with the capacitance electrode in a plan view is provided on at least one side of the capacitance wiring line in a line width direction, and a part of the capacitance of the capacitor is formed between the gate electrode and the capacitance wiring line in the portion not overlapping with the capacitance electrode.

9. The display device according to claim 1,
wherein the thin film transistor is a drive thin film transistor.

10. The display device according to claim 9,
wherein the capacitance electrode is provided with a second opening exposing the first interlayer insulating film,
a contact hole is provided in the first interlayer insulating film and the second interlayer insulating film in the second opening, and
a connection wiring line electrically connected to the gate electrode via the contact hole is provided as the third metal layer on the second interlayer insulating film.

11. The display device according to claim 10,
wherein the capacitance wiring line is provided along circumferential ends of the gate electrode and the second opening, at an inner side of the circumferential ends, and is provided in a U-shape not overlapping with the connection wiring line in a plan view.

12. The display device according to claim 11,
wherein the semiconductor layer includes a channel region overlapping with the gate electrode in a plan view, and a pair of conductor regions sandwiching the channel region, and
an intermediate portion of the channel region includes a recessed portion provided in a U-shape in a plan view.

13. The display device according to claim 12,
wherein the second opening overlaps with the recessed portion in a plan view.

14. The display device according to claim 13,
wherein the connection wiring line intersects the channel region in the recessed portion.

15. The display device according to claim 1,
wherein the light-emitting element is an organic electroluminescence element.

16. A method for manufacturing a display device, comprising:
forming a thin film transistor layer on a base substrate for each of subpixels, a thin film transistor and a capacitor being arranged on the thin film transistor layer; and
forming a light-emitting element layer on the thin film transistor layer, a light-emitting element being arranged in the light-emitting element layer for each of the subpixels,
wherein the thin film transistor includes a semiconductor layer, a gate insulating film covering the semiconductor layer, and a gate electrode provided as a first metal layer on the gate insulating film and arranged in an island shape overlapping with a part of the semiconductor layer in a plan view,
the capacitor includes the gate electrode, a first interlayer insulating film provided on the gate electrode, a capacitance electrode provided as a second metal layer on the first interlayer insulating film and overlapping with the gate electrode in a plan view, and a capacitance wiring line provided as a third metal layer on the capacitance electrode and overlapping with the capacitance electrode and the gate electrode in a plan view,
the forming of the thin film transistor layer includes:
forming, after forming a semiconductor film on the base substrate, a semiconductor layer by patterning the semiconductor film;
forming, on the semiconductor layer, the gate insulating film covering the semiconductor layer;
forming, after forming a first metal film on the gate insulating film, the first metal layer by patterning the first metal film, the first metal layer including the gate electrode;
forming the first interlayer insulating film on the gate electrode;
forming, after forming a second metal film on the first interlayer insulating film, the second metal layer by patterning the second metal film, the second metal layer including the capacitance electrode;
forming the second interlayer insulating film on the capacitance electrode; and
forming, after forming a third metal film on the second interlayer insulating film or the capacitance electrode, the third metal layer by patterning the third metal film, the third metal layer including the capacitance wiring line electrically connected to the capacitance electrode, and
in the forming of the third metal layer, the capacitance wiring line is formed having a line width equal to or greater than a line width of the capacitance electrode and equal to or less than a line width of the gate electrode.

17. The method for manufacturing a display device according to claim 16,
wherein the forming of the thin film transistor layer further includes, after the forming of the second interlayer insulating film and before the forming of the third metal layer:
forming a first opening in the second interlayer insulating film by patterning the second interlayer insulating film, the first opening extending through the second interlayer insulating film, and
in the forming of the first opening, the first opening is formed overlapping with the capacitance wiring line in a plan view and exposing the capacitance electrode or the first interlayer insulating film along a circumferential end of the capacitance electrode.

18. The method for manufacturing a display device according to claim 17,
wherein, in the forming of the first opening, the first opening is formed having a length in a line width direction of the capacitance electrode being equal to or greater than a line width of the capacitance electrode and equal to or less than a line width of the gate electrode.

19. The method for manufacturing a display device according to claim 16,
wherein the forming of the thin film transistor layer further includes, after the forming of the second interlayer insulating film and before the forming of the third metal layer:
forming a first opening in the second interlayer insulating film by patterning the second interlayer insulating film, the first opening extending through the second interlayer insulating film, and
in the forming of the first opening, the first opening exposing the capacitance electrode is formed in a hole shape.

20. The method for manufacturing a display device according to claim 16,
wherein the light-emitting element is an organic electroluminescence element.
